(19) United States
(12) Patent Application Publication
(10) Pub. No.: US 2026/0190422 A1
(43) Pub. Date: Jul. 2, 2026

(54) Semiconductor device

(71) Applicant: Vanguard International Semiconductor Corporation, Hsinchu (TW)

(72) Inventors: Ting-En Hsieh, Hsinchu City (TW); Yi-Wei Lien, Hsinchu (TW); Hsin-Chang Tsai, Kaohsiung City (TW); Wei-Chih Cheng, Tainan City (TW)

(73) Assignee: Vanguard International Semiconductor Corporation, Hsinchu (TW)

(21) Appl. No.: 19/008,571

(22) Filed: Jan. 2, 2025

(51) Int. Cl. H10D 64/23; H10D 30/01; H10D 30/47; H10D 62/85; H10D 64/00

(52) U.S. Cl. CPC H10D 64/256; H10D 30/015; H10D 30/475; H10D 62/8503; H10D 64/111

(57) ABSTRACT

A semiconductor device includes a substrate, a semiconductor channel layer, a semiconductor barrier layer, a source electrode, a gate electrode, and a drain stacking layer. The drain stacking layer includes a first drain layer which includes a first body portion and a first extension portion, a second drain layer which includes a second body portion and a second extension portion, and a third drain layer which includes a third body portion and a third extension portion. A length of the second drain layer is greater than a length of the first drain layer in a first direction. A bottom surface of the first extension portion is higher than a top surface of the first body portion, and a top surface of the second extension portion is higher than a top surface of the second body portion.

### BACKGROUND OF THE INVENTION

### 1. Field of the Invention

This disclosure relates to a semiconductor device, especially to a semiconductor device used for withstanding high voltage.

### 2. Description of the Prior Art

In semiconductor industry, III-V semiconductor compounds can be used in various integrated circuit components, such as high-power field-effect transistors, high-frequency transistors, or high electron mobility transistors (HEMTs). HEMTs belong to a type of transistor that features a two-dimensional electron gas (2DEG), which exists at the interface between two materials with different band gaps (i.e., a heterojunction). Unlike conventional transistors that use doped regions as the carrier channel, HEMTs use the 2DEG as the carrier channel. This gives HEMTs several attractive characteristics compared to traditional metal-oxide-semiconductor field-effect transistors (MOSFETs), such as high electron mobility and the ability to transmit signals at high frequencies.

Conventional HEMTs include a compound semiconductor channel layer, a compound semiconductor barrier layer, a compound semiconductor cap layer, and a gate electrode, which are stacked in sequence. By applying a bias to the gate electrode on the compound semiconductor cap layer, the concentration of the two-dimensional electron gas in the compound semiconductor channel layer beneath the cap layer can be controlled, thereby regulating the switching of the HEMTs. Additionally, conventional HEMTs may also incorporate field plates to control the electric field distribution, which increases the breakdown voltage of the HEMT.

However, when field plates are incorporated into HEMTs, the typically uneven morphology of the field plates can lead to structural defects in the interlayer dielectric layer near the field plates, thereby reducing the breakdown strength of the HEMT.

### SUMMARY OF THE INVENTION

In light of this, it is necessary to provide an improved semiconductor device to address the deficiencies present in conventional semiconductor devices.

According to an embodiment disclosed herein, a semiconductor device is provided, which includes a substrate; a semiconductor channel layer and a semiconductor barrier layer disposed on the substrate; a gate electrode disposed on the semiconductor barrier layer; a first interlayer dielectric layer disposed on the semiconductor barrier layer and the gate electrode; a source electrode located on one side of the gate electrode; and a drain stack layer disposed on the other side of the gate electrode, laterally separated from the gate electrode. The drain stack layer includes: a first drain layer, which comprises a first body portion and a first extension portion, where the first extension portion covers a portion of the first interlayer dielectric layer, and a bottom surface of the first extension portion is higher than a top surface of the first body portion; a second drain layer, disposed on the first drain layer, which includes a second body portion and a second extension portion, where the second extension portion covers the second interlayer dielectric layer, and along a first direction, a length of the second drain layer is greater than a length of the first drain layer, and a top surface of the second extension portion is higher than a top surface of the second body portion; and a third drain layer, disposed on the second drain layer, which includes a third body portion and a third extension portion.

Additionally, according to other embodiments disclosed herein, a method for manufacturing a semiconductor device is proposed, which includes the following steps: providing a substrate sequentially comprising a base, a semiconductor channel layer, and a semiconductor barrier layer from bottom to top; forming a gate electrode on the bottom dielectric layer; forming a first interlayer dielectric layer covering the gate electrode; forming a source electrode on one side of the gate electrode; forming a first drain layer on the other side of the gate electrode, wherein the first drain layer comprises a first body portion and a first extension portion, and the first extension portion covers a portion of the first interlayer dielectric layer; and forming a second drain layer on the first drain layer, wherein the second drain layer comprises a second body portion and a second extension portion, and the second extension portion covers a second interlayer dielectric layer, wherein a length of the second drain layer is greater than a length of the first drain layer in a first direction, and a top surface of the second extension portion is higher than a top surface of the second body portion.

According to the aforementioned embodiment, the drain stack layer includes the first drain layer, the second drain layer, and the third drain layer, where the second extension portion of the second drain layer covers and extends beyond the extension portion of the first drain layer. By offsetting the ends of the extension portions of these drain layers, not only can the peak of the electric field near the tip of the drain stack layer be effectively reduced to enhance the breakdown strength of the semiconductor device during wafer testing, but it also allows each drain layer to have a flatter surface morphology. This effectively reduces structural defects, such as voids, in the adjacent interlayer metal dielectric, and further improves the semiconductor device's ability to withstand high voltages.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

Aspects of the present disclosure are best understood from the following detailed description when read with the accompanying figures. It is noted that, in accordance with the standard practice in the industry, various features may not be drawn to scale. In fact, the dimensions of the various features may be arbitrarily increased or reduced for clarity of discussion.

FIG. 1 is a cross-sectional schematic diagram of a semiconductor device illustrated according to an embodiment of this disclosure.

FIG. 2 is an enlarged cross-sectional schematic diagram of a partial region of the semiconductor device illustrated according to an embodiment of this disclosure.

FIG. 3 is an enlarged cross-sectional schematic diagram of another partial region of the semiconductor device illustrated according to an embodiment of this disclosure.

FIG. 4 is an enlarged cross-sectional schematic diagram of yet another partial region of the semiconductor device illustrated according to an embodiment of this disclosure.

FIG. 5 is an enlarged cross-sectional schematic diagram of a further partial region of the semiconductor device illustrated according to an embodiment of this disclosure.

FIGS. 6 to 10 are cross-sectional schematic diagrams illustrating various stages in the manufacturing process of the semiconductor device according to some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “over,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as “below” and/or “beneath” other elements or features would then be oriented “above” and/or “over” the other elements or features. The apparatus may be otherwise oriented (rotated 90 degrees or at other orientations) and the spatially relative descriptors used herein may likewise be interpreted accordingly.

It is understood that, although the terms first, second, third, etc. may be used herein to describe various elements, components, regions, layers and/or sections, these elements, components, regions, layers and/or sections should not be limited by these terms. These terms may be only used to distinguish one element, component, region, layer and/or section from another region, layer and/or section. Terms such as “first,” “second,” and other numerical terms when used herein do not imply a sequence or order unless clearly indicated by the context. Thus, a first element, component, region, layer and/or section discussed below could be termed a second element, component, region, layer and/or section without departing from the teachings of the embodiments.

As disclosed herein, the term “about” or “substantial” generally means within 20%, 10%, 5%, 3%, 2%, 1%, or 0.5% of a given value or range. Unless otherwise expressly specified, all of the numerical ranges, amounts, values and percentages disclosed herein should be understood as modified in all instances by the term “about” or “substantial”. Accordingly, unless indicated to the contrary, the numerical parameters set forth in the present disclosure and attached claims are approximations that can vary as desired.

Furthermore, as disclosed herein, the terms “coupled to” and “electrically connected to” include any directly and indirectly electrical connecting means. Therefore, if it is described in this document that a first component is coupled or electrically connected to a second component, it means that the first component may be directly connected to the second component, or may be indirectly connected to the second component through other components or other connecting means.

As disclosed herein, the term “Group III-V semiconductor” refers to compound semiconductors that include at least one Group III element and at least one Group V element. The Group III elements can be boron (B), aluminum (Al), gallium (Ga), or indium (In), while the Group V elements can be nitrogen (N), phosphorus (P), arsenic (As), or antimony (Sb). Furthermore, “III-V semiconductors” can include: aluminum nitride (AlN), gallium nitride (GaN), indium phosphide (InP), aluminum arsenide (AlAs), gallium arsenide (GaAs), aluminum gallium nitride (AlGaN), indium aluminum gallium nitride (InAlGaN), gallium indium nitride (GaInN), gallium indium phosphide (GaInP), aluminum gallium arsenide (AlGaAs), aluminum indium arsenide (AlInAs), gallium indium arsenide (GaInAs), and similar compounds or combinations of the aforementioned, but are not limited to these. Additionally, depending on the requirements, III-V semiconductors may also include dopants, resulting in III-V semiconductors with specific conductivity types, such as n-type or p-type III-V semiconductors.

Although the disclosure is described with respect to specific embodiments, the principles of the disclosure, as defined by the claims appended herein, can obviously be applied beyond the specifically described embodiments of the disclosure described herein. Moreover, in the description of the present disclosure, certain details have been left out in order to not obscure the inventive aspects of the disclosure. The details left out are within the knowledge of a person having ordinary skill in the art.

This disclosure relates to a semiconductor device that exhibits good high-voltage performance, suitable for the design of high electron mobility transistors (HEMTs).

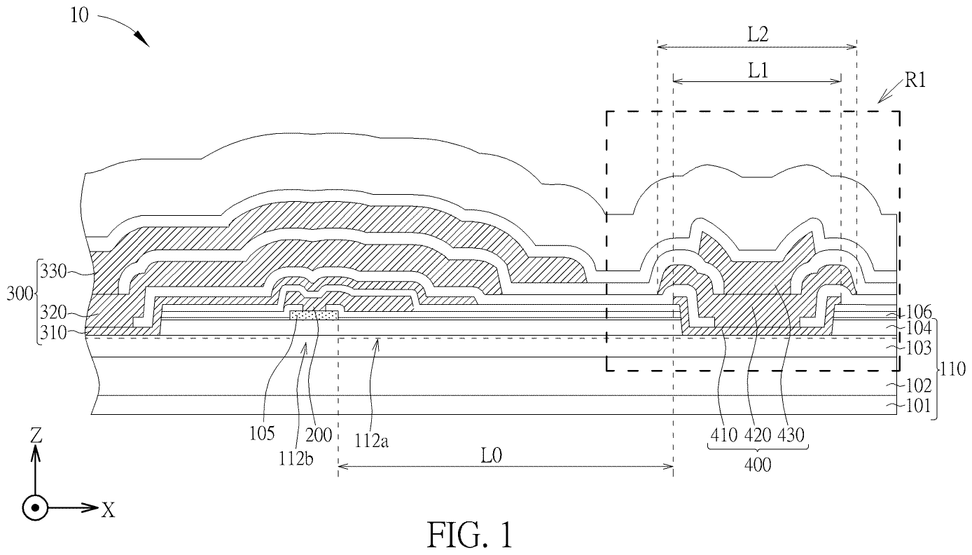

FIG. 1 is a cross-sectional schematic diagram of a semiconductor device illustrated according to an embodiment of this disclosure. As shown in FIG. 1, the semiconductor device 10, such as a high electron mobility transistor, includes the substrate 101, and the buffer layer 102, the semiconductor channel layer 103, the semiconductor barrier layer 104, and the semiconductor cap layer 105 can be optionally disposed on the substrate 10 in sequence. For convenience of description, the substrate 101, the buffer layer 102, the semiconductor channel layer 103, and the semiconductor barrier layer 104 can collectively be referred to as the semiconductor layer 110, which may also include non-semiconductor layers, such as metal layers or insulating layers, depending on different requirements. The gate electrode 200 can be disposed on top of the semiconductor barrier layer 104, the source electrode 300 can be placed on one side of the gate electrode 200, and the drain stack layer 400 is disposed on the other side of the gate electrode 200, such that the source electrode 300 and the drain stack layer 400 are located on different sides of the gate electrode 200. The drain stack layer 400 may include a first drain layer 410, a second drain layer 420, and a third drain layer 430, stacked sequentially from bottom to top.

According to an embodiment of this disclosure, the substrate 101 may include semiconductor substrates, glass substrates, or ceramic substrates, such as silicon substrate, silicon-germanium substrate, silicon carbide, aluminum nitride substrate, sapphire substrate, combinations of the foregoing, or similar materials, but the embodiments of this disclosure are not limited thereto. According to another embodiment, the substrate 101 may also include a semiconductor-on-insulator (SOI) substrate, formed by depositing semiconductor material on an insulating layer. In another embodiment, the substrate 101 can be a composite substrate consisting of a core substrate and a cladding layer (also called a wrapping layer), such as a QST (Qromis Substrate Technology) substrate, where the back of the core substrate can be exposed from the cladding layer. The core substrate can include ceramics, silicon carbide, aluminum nitride, sapphire, or silicon. The cladding layer can be a composite material layer including an insulating material layer and a semiconductor material layer, where the insulating material layer can be single or multiple layers of silicon oxide, silicon nitride, or silicon oxynitride, and the semiconductor material layer can be silicon or polysilicon. Since the thermal conductivity of the QST substrate is more than hundred times that of a silicon substrate, using a QST substrate can provide excellent heat dissipation capabilities.

According to an embodiment of this disclosure, the buffer layer 102 can be used to reduce the mismatch of stress or mismatch of lattice between the substrate 101 and the semiconductor channel layer 103. In one embodiment, the buffer layer 102 may include multiple sub-semiconductors, and its overall resistance value is higher than the resistance values of other layers on the substrate 101. Specifically, the proportion of certain elements, such as metal elements, in the buffer layer 102 will gradually change from the substrate 101 towards the semiconductor channel layer 103.

According to an embodiment of this disclosure, the material of the semiconductor channel layer 103 may include one or more III-V semiconductor materials, such as III-nitride compounds. For example, the material of the semiconductor channel layer 103 can be aluminum nitride (AlN), aluminum gallium nitride (AlGaN), aluminum indium nitride (AlInN), indium gallium aluminum nitride (InGaAlN), similar materials, or combinations thereof, but the embodiments of this disclosure are not limited thereto. Additionally, the semiconductor channel layer 103 can be doped or undoped.

According to an embodiment of this disclosure, the material of the semiconductor barrier layer 104 may include III-V semiconductor materials, such as III-nitride compounds. For instance, the semiconductor barrier layer 104 may include AlN, AlGaN, AlInN, InGaAlN, similar materials, or combinations thereof, but the embodiments of this disclosure are not limited thereto. The semiconductor barrier layer 104 can be a single-layer structure or multi-layer structure, and can be doped or undoped.

According to an embodiment of this disclosure, the semiconductor device 10 can further include a semiconductor cap layer 105 disposed on the semiconductor barrier layer 104. Referring to FIG. 1, due to the discontinuous bandgap between the semiconductor channel layer 103 and the semiconductor barrier layer 104, when stacking the semiconductor channel layer 103 and the semiconductor barrier layer 104, electrons are gathered at the heterojunction between these layers due to the piezoelectric effect, and thus a high electron mobility thin layer is created, namely the two-dimensional electron gas (2DEG) region 112a. In contrast, for the areas covered by the semiconductor cap layer 105, no two-dimensional electron gas is formed, and can be considered as a 2DEG cutoff region 112b. The semiconductor cap layer 105 can be a doped single-layer or multiple-layer III-V semiconductor, such as a p-type III-V semiconductor layer. For a p-type III-V semiconductor layer, the dopants can be C, Fe, Mg, or Zn; and according to one embodiment of this disclosure, the semiconductor cap layer 105 can be a p-type GaN layer.

According to an embodiment of this disclosure, the gate electrode 200 can be a single-layer or multi-layer structure, which can be disposed on the semiconductor cap layer 105, and is electrically connected to the underlying semiconductor cap layer 105, such as a Schottky contact. The composition of the gate electrode 200 can be TiN, W, Pt, Ni, Ti, Al, Au, Mo, the stacked layers thereof, or the alloys thereof, but is not limited thereto.

According to an embodiment of this disclosure, the source electrode 300 may include at least one source layer, such as multiple source layers stacked along the Z-direction, for example, a first source layer 310, a second source layer 320, and a third source layer 330. The composition of the first source layer 310, second source layer 320, and third source layer 330 may include conductive metals, such as W, Pt, Ni, Ti, Al, Au, Mo, or alloys of these metals, and each layer may include stacked layers of these metals or alloys, but the embodiments of this disclosure are not limited thereto. As shown in FIG. 1, the first source layer 310, second source layer 320, and third source layer 330 in the source electrode 300 are extend in the same direction (e.g., X direction) towards the drain stack layer 400. According to an embodiment of this disclosure, at least one source layer in the source electrode 300 can cover and extend over the top of the gate electrode 200 to prevent electric field concentration at the bottom tip of the gate electrode 200.

According to an embodiment of this disclosure, the compositions of the first drain layer 410, second drain layer 420, and third drain layer 430 can each include conductive metals, such as W, Pt, Ni, Ti, Al, Au, Mo, the stacked layers thereof, or the alloys thereof, but the embodiments of this disclosure are not limited thereto.

According to an embodiment of this disclosure, an optional passivation layer 106 can be formed on the semiconductor layer 110, covering the top surface of the semiconductor barrier layer 104. The passivation layer 106 can be used to eliminate or reduce surface defects existing on the top surface of the semiconductor barrier layer 104 and the side surfaces of the semiconductor cap layer 105, thereby improving the electrical performance of the semiconductor device 10. According to an embodiment of this disclosure, the composition of the passivation layer 106 may include any suitable dielectric material, such as silicon nitride (Si₃N₄), silicon oxynitride (SiON), aluminum nitride (AlN), aluminum oxide (Al₂O₃), silicon oxide (SiO₂), similar materials, or combinations thereof, but the embodiments of this disclosure are not limited thereto.

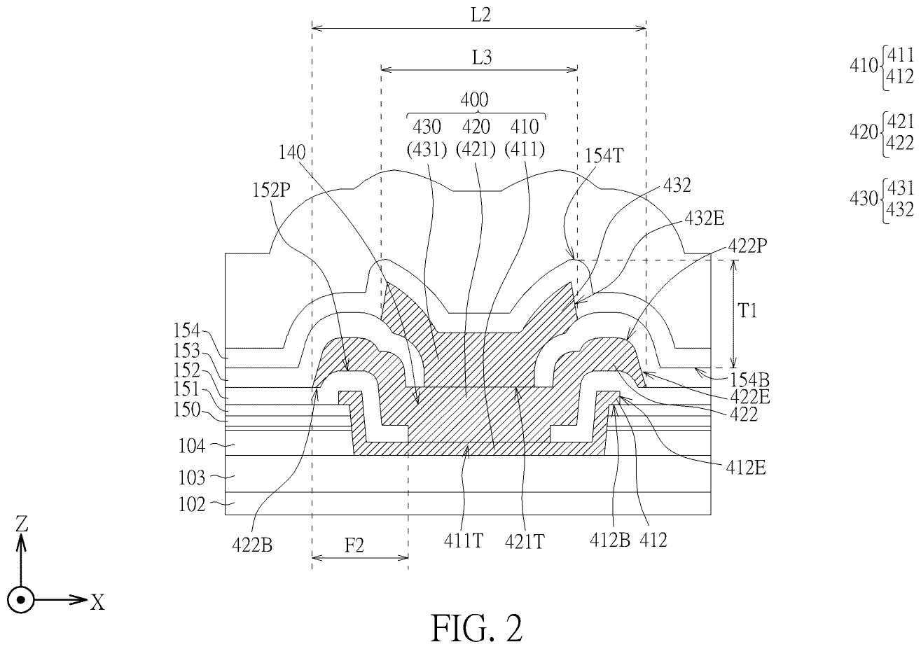

FIG. 2 is an enlarged view of the partial region R1 of FIG. 1 according to an embodiment of this disclosure. As shown in FIG. 2, multiple dielectric layers can be disposed above the semiconductor barrier layer 104, such as a bottom dielectric layer 150, a first interlayer dielectric layer 151, a second interlayer dielectric layer 152, a third interlayer dielectric layer 153, and a fourth interlayer dielectric layer 154, which can be sequentially stacked from bottom to top on the semiconductor barrier layer 104. The material of each dielectric layer can be selected from Si₃N₄, AlN, Al₂O₃, SiO₂, SiON, or combinations thereof, but the embodiments of this disclosure are not limited thereto.

The drain opening 140 can be disposed at least in the bottom dielectric layer 150, for example, disposed in the bottom dielectric layer 150 and the first interlayer dielectric layer 151, which can be used to accommodate part of the drain stack layer 400, allowing the drain stack layer 400 to electrically connect to the underlying semiconductor channel layer 103 through the drain opening 140.

The first drain layer 410, the second drain layer 420, and the third drain layer 430 of the drain stack layer 400 each has a body portion and an extension portion. Specifically, the first drain layer 410 includes a first body portion 411 and a first extension portion 412, with the top surface 411T of the first body portion 411 disposed in the drain opening 140, and the first extension portion 412 conformally covering the sidewalls of the drain opening 140 and a part of the first interlayer dielectric layer 151, such that the bottom surface 412B of the first extension portion 412 can be higher than the top surface 411T of the first body portion 411. The second drain layer 420 is disposed on the first drain layer 410 and includes a second body portion 421 and a second extension portion 422, with the bottom surface of the second body portion 422 located in the drain opening 140. The third drain layer 430 is disposed on the second drain layer 420 and includes a third body portion 431 and a third extension portion 432.

Referring to FIG. 2, according to an embodiment of this disclosure, the first interlayer dielectric layer 151 is disposed between the first extension portion 412 and the bottom dielectric layer 150, the second interlayer dielectric layer 152 is disposed between the second extension portion 422 and the first extension portion 412, and the third interlayer dielectric layer 153 is disposed between the third extension portion 432 and the second extension portion 422. According to an embodiment of this disclosure, with reference to FIGS. 1 and 2, the first interlayer dielectric layer 151 can cover the gate electrode 200 and the bottom dielectric layer 150, and isolate the gate electrode 200 from the source electrode 300. The second interlayer dielectric layer 152 can extend into the drain opening 140, disposed above the first body portion 411, and cover the top surface 411T of the first body portion 411, such that the first extension portion 412 and the second extension portion 422 are vertically separated from each other. Similarly, the third interlayer dielectric layer 153 can extend above the second body portion 421 and directly contact the top surface 421T of the second body portion 421. According to an embodiment of this disclosure, the material of the first interlayer dielectric layer 151, second interlayer dielectric layer 152, and third interlayer dielectric layer 153 can be selected from Si₃N₄, AlN, Al₂O₃, SiO₂, SiON, or combinations thereof, but the embodiments of this disclosure are not limited thereto. According to an embodiment of this disclosure, these dielectric layers can be formed through deposition processes such as chemical vapor deposition, atomic layer deposition, spin coating, similar deposition processes, or combinations thereof, but the embodiments of this disclosure are not limited thereto.

According to an embodiment of this disclosure, the second interlayer dielectric layer 152 can cover the first extension portion 412, such that the surface of the second interlayer dielectric layer 152 may include at least one raised profile (or referred to as a raised region 152P), with the raised region 152P disposed directly above the first extension portion 412. The second extension portion 422 covers and extends beyond the second interlayer dielectric layer 152, so that the length L2 of the second drain layer 420 along the X direction can be greater than the length L1 of the first drain layer 410 along the X direction, and the second extension portion 422 extends beyond the end edge 412E of the first extension portion 412. According to an embodiment of this disclosure, the second extension portion 422 can have a raised profile (or referred to as a raised region 422P), with the raised region 422P disposed directly above the first extension portion 412. The raised region 422P includes an arc-shaped top surface, such that the apex of the raised region 422P of the second extension portion 422 is higher than the top surface 421T of the second body portion 421, or can further make the vertex of the raised region 152P of the second interlayer dielectric layer 152 higher than the bottom surface 422B of the second extension portion 422. According to an embodiment of this disclosure, the bottom surface 422B of the second extension portion 422 can also be at the same height as or lower than the top surface 421T of the second body portion 421.

According to an embodiment of this disclosure, both the second extension portion 422 and the first extension portion 412 can serve as field plates for the semiconductor device 10. Referring to FIGS. 1 and 2, for the second extension portion 422, considering the impact of the second extension portion 422 on the electric field of the extension portion of the source electrode 300 and the drift region when serving as a field plate, the length F2 of the second extension portion 422 along the X direction must have an appropriate length, for example, 5%-30% of the distance L0 between the drain stack layer 400 and the gate electrode 200 (referring to FIG. 1). The distance L0 can also be viewed as the length of the drift region of the semiconductor device 10.

By extending the second extension portion 422 beyond the end edge 412E of the first extension portion 412, it can not only effectively reduce the peak value of the electric field near the top of the raised region 422P of the second drain layer 420, thereby improving the breakdown voltage of the semiconductor device 10 during chip testing, but also make the surface morphology of the second drain layer 420 more flat. This can effectively reduce structural defects, such as voids, in the interlayer dielectric layers stacked on top of it, further enhancing the semiconductor device 10's ability to withstand high voltages.

Referring again to FIG. 2, according to an embodiment of this disclosure, the third extension portion 432 of the third drain layer 430 can cover part of the second extension portion 422 of the second drain layer 420, so the length L3 of the third drain layer along the X direction will be smaller than the length L2 of the second drain layer along the X direction, and the third extension portion 432 can be laterally separated from the first interlayer dielectric layer 151.

According to an embodiment of this disclosure, the semiconductor device 10 can further include a fourth interlayer dielectric layer 154 covering and directly contacting the third drain layer 430 and the third interlayer dielectric layer 153, wherein above the drain stack layer 400, there is a vertical distance T1 between the highest point 154T and the lowest point 154B of the top surface of the fourth interlayer dielectric layer 154. The magnitude of this distance T1 can serve as a basis for determining the flatness of the fourth interlayer dielectric layer 154.

By retracting and separating the end edge 432E of the third extension portion 432 from the end edge 422E of the second extension portion 422, it can not only effectively reduce the peak value of the electric field near the top of the third drain layer 430, thereby improving the breakdown voltage of the semiconductor device 10 during chip testing, but also make the surface morphology of the third drain layer 430 more flat. This can effectively reduce structural defects, such as voids, in the interlayer dielectric layers stacked on top of it, further enhancing the semiconductor device 10's ability to withstand high voltages.

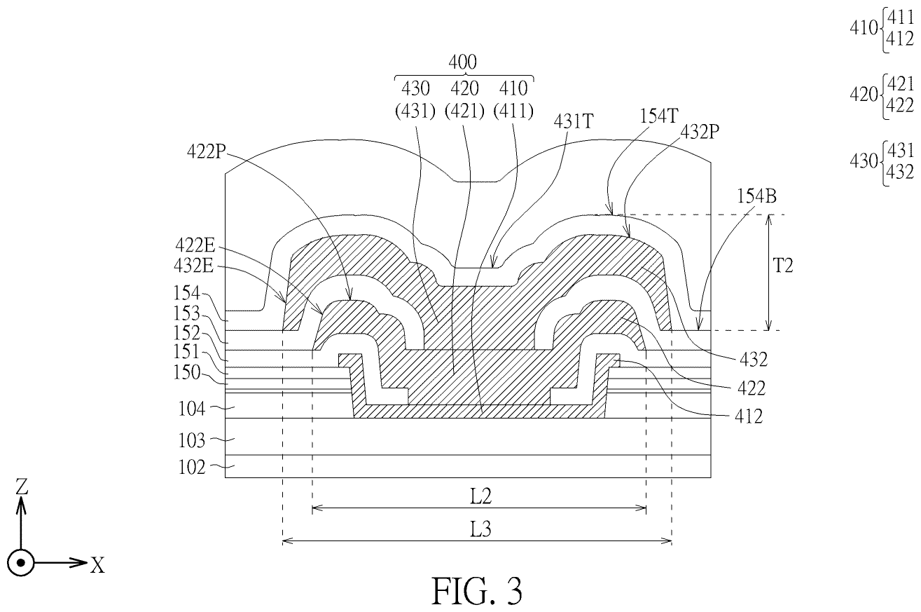

FIG. 3 is an enlarged view of the partial region R1 of FIG. 1 according to another embodiment of this disclosure. According to an embodiment of this disclosure, while similar to the embodiment in FIG. 2, the difference between the two embodiments is that the third extension portion 432 of the third drain layer 430 can cover and extend beyond the second extension portion 412 of the second drain layer 420, such that the length L3 of the third drain layer 430 along the X direction is greater than the length L2 of the second drain layer 420 along the X direction, and the end edge 432E of the third extension portion 432 extends beyond the end edge 422E of the second extension portion 422. According to an embodiment of this disclosure, the third extension portion 432 covering the third interlayer dielectric layer 153 can form at least one raised profile (or referred to as a raised region 432P) above the second extension portion 422, with the raised region 432P forming a top surface that includes at least one arc shape. Since the top surface of the raised region 422P of the second extension portion 422 is disposed directly above the first extension portion 412, the top surface of the raised region 432P of the third extension portion 432 can also be disposed directly above the first extension portion 412. Additionally, above the drain stack layer 400, there is a vertical distance T2 between the highest point 154T and the lowest point 154B of the top surface of the fourth interlayer dielectric layer 154.

By extending the third extension portion 432 beyond the end edge 422E of the second extension portion 422, it can not only effectively reduce the peak value of the electric field near the top of the raised region 432P of the third drain layer 430, thereby improving the breakdown voltage of the semiconductor device 10 during chip testing, but also make the surface morphology of the third drain layer 430 more flat. This can effectively reduce structural defects, such as voids, in the interlayer dielectric layers stacked on top of it, further enhancing the semiconductor device 10's ability to withstand high voltages.

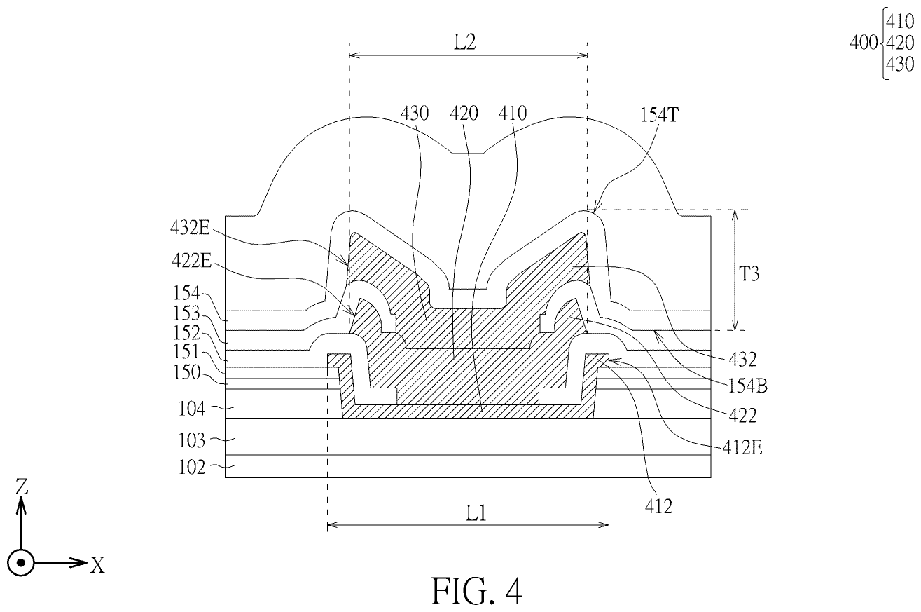

Referring to FIG. 4, which is an enlarged view of the partial region R1 of FIG. 1 according to another embodiment of this disclosure. The embodiment shown in FIG. 4 is similar to the embodiment in FIG. 2, with the difference being that the length L2 of the second drain layer 420 along the X direction is approximately the same as the length L1 of the first drain layer 410 along the X direction. Therefore, its second extension portion 422 only partially covers the first extension portion 412, and the end edge 422E of the second extension portion 422 is disposed above the first extension portion 412 without extending beyond it. Similarly, the length of the third drain layer 430 along the X direction is also similar to the second drain layer 420, such that the end edge 432E of the third extension portion 432 is also disposed above the first extension portion 412 without extending beyond it. In this configuration, the end edges 412E, 422E, and 432E of each drain layer are not staggered. This arrangement causes the fourth interlayer dielectric layer 154 to form a steep surface when deposited at the end of the third extension portion 432, with the vertical distance T3 between its highest point 154T and bottom surface 154B being equivalent to the total length of the end edges 422E and 432E of the second and third extension portions along the Z direction. In the embodiments of FIGS. 2 and 3, the staggered end edges of each drain layer result in a relatively flat surface morphology of the fourth interlayer dielectric layer 154. However, in the embodiment shown in FIG. 4, the unstaggered end edges cause the distance T3 to be significantly larger than distances T1 and T2. Consequently, compared to the embodiments in FIGS. 2 and 3, this configuration is less effective in reducing the peak value of the electric field near the top of the third drain layer 430. The steep surface morphology at the end edge 432E of the third drain layer 430 is more likely to cause structural defects, such as voids, in the dielectric layers stacked on top of it, which is detrimental to the high-voltage performance of the semiconductor device 10 during chip testing.

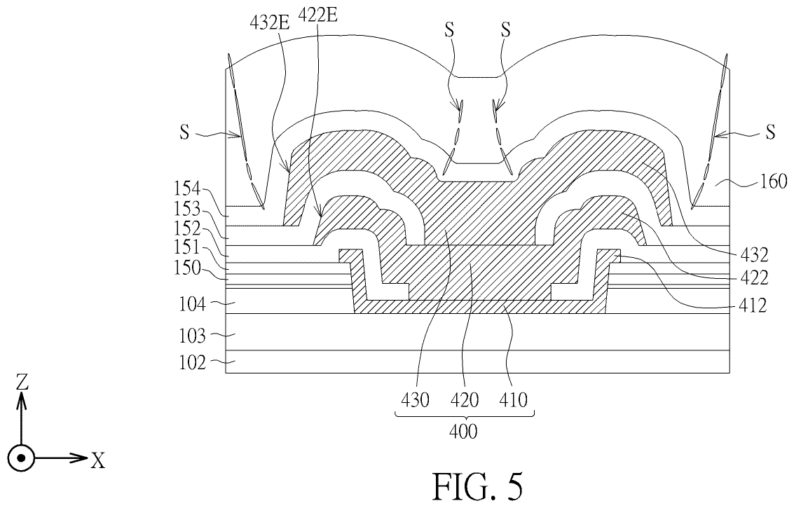

Referring to FIG. 5, which is an enlarged view of the partial region R1 of FIG. 1 according to an embodiment of this disclosure. As shown in FIG. 5, voids S exist in the inter-metal dielectric layer 160 above the drain stack layer 400, located at the end of the third extension portion 432 and the third body portion 431, and extending upward approximately along a diagonal direction (e.g., XZ direction). The voids S can be discontinuously or continuously distributed within the inter-metal dielectric layer 160. Compared to the embodiment where the end edges 422E of the second drain layer 420 and 432E of the third drain layer 430 are not staggered (as shown in FIG. 4), by staggering the end edges 422E of the second drain layer 420 and 432E of the third drain layer 430, even if the fourth interlayer dielectric layer 154 at the end edge 432E of the third drain layer 430 still has a steep surface morphology (as shown in FIGS. 2, 3, and 5), its steep distance is shorter. Therefore, even if voids S exist, their maximum size (e.g., length) will not be too large, such as being less than 5 nanometers, or even having no voids at all. Consequently, this configuration can improve the breakdown voltage of the semiconductor device 10 during chip testing.

In order to enable a person having ordinary skill in the art to implement the invention disclosed herein, a manufacturing method of the semiconductor device of this disclosure is described below.

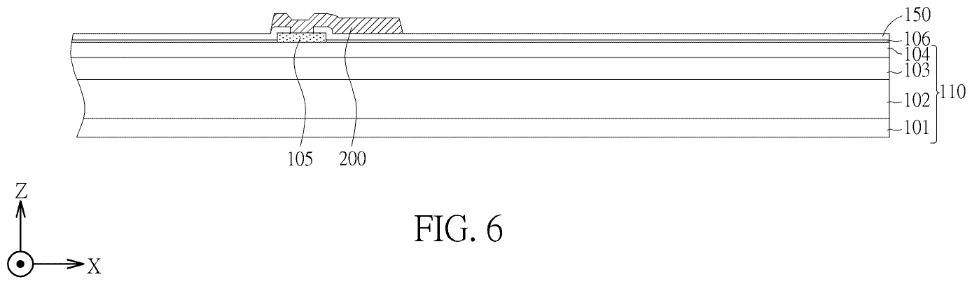

FIGS. 6 to 10 illustrate cross-sectional schematic diagrams of various stages in manufacturing a semiconductor device. Referring to FIG. 6, according to an embodiment of this disclosure, a buffer layer 102, a semiconductor channel layer 103, a semiconductor barrier layer 104, a passivation layer 106, and a bottom dielectric layer 150 can be sequentially disposed on the substrate 101 of semiconductor device 10. It is noted that the substrate 101, the buffer layer 102, the semiconductor channel layer 103, and the semiconductor barrier layer 104 can collectively be referred to as semiconductor layer 110. Additionally, a semiconductor cap layer 105 can be disposed above the semiconductor barrier layer 104 to create a depletion of two-dimensional electron gas beneath the gate electrode 200, and thus achieve a normally-off state for the semiconductor device. The gate opening 120 can be formed in the bottom dielectric layer 150 to expose the underlying semiconductor cap layer 105. The stacked layers on substrate 101 can be formed through various suitable methods, including Molecular Beam Epitaxy (MBE), Metal-Organic Chemical Vapor Deposition (MOCVD), Hydride Vapor Phase Epitaxy (HVPE), Atomic Layer Deposition (ALD), and other appropriate deposition techniques.

Then, referring to FIG. 6, a gate metal layer (not shown) can be formed on the top surface of the bottom dielectric layer 150 and within the gate opening 120 through a suitable deposition process, for example, a composite conductive layer including Schottky contact metal. The gate metal layer thickness can be 500 to 2000 Å, but is not limited thereto. Subsequently, a patterning process is performed on the gate metal layer to form the gate electrode 200.

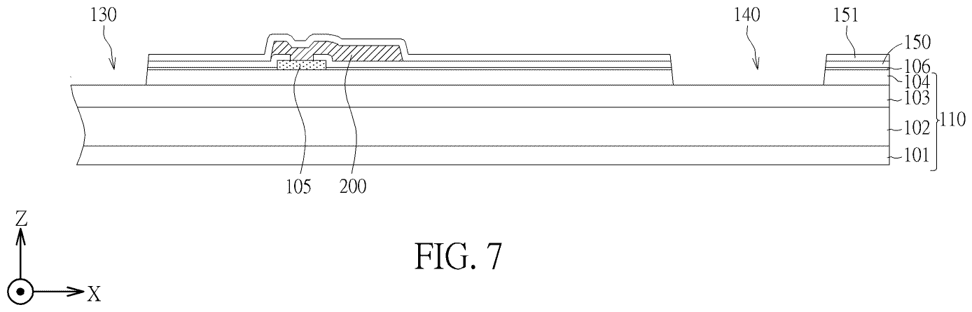

Referring to FIG. 7, according to an embodiment of this disclosure, after completing the process in FIG. 6, a first interlayer dielectric layer 151 can be conformally formed on the semiconductor layer 110 and gate electrode 200, and then the first interlayer dielectric layer 151 is etched to form a source opening 130 and a drain opening 140. The first interlayer dielectric layer 151 can be formed through suitable deposition processes, such as chemical vapor deposition, spin coating, similar deposition processes, or the combination thereof, but the embodiments of this disclosure are not limited thereto.

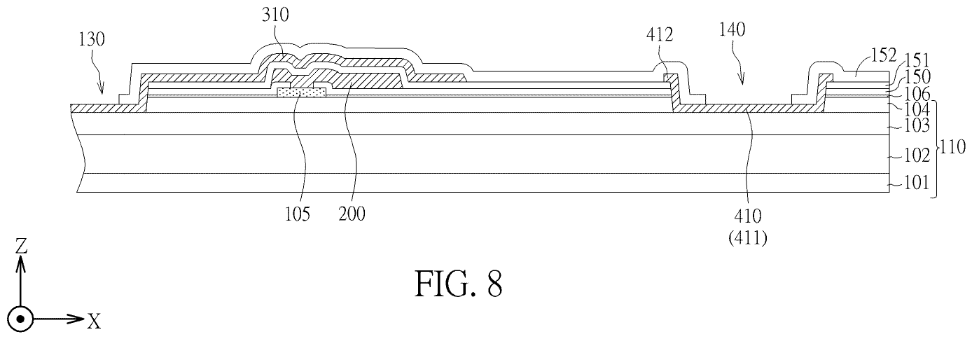

Referring to FIG. 8, according to an embodiment of this disclosure, after completing the process in FIG. 7, a first conductive material layer (not shown) can be formed on the semiconductor layer 110, and then a patterning process is performed on the first conductive material layer to simultaneously form the first source layer 310 and first drain layer 410 that are mutually separated, avoiding electrical connection between the first source layer 310 and first drain layer 410 that could cause a short circuit. The first conductive material layer can be formed through a deposition process, with its composition including conductive metals, such as W, Pt, Ni, Ti, Al, Au, Mo, the stacked layers thereof, or the alloys thereof, but the embodiments of this disclosure are not limited thereto. The first source layer 310 is formed in the source opening 130, and the first drain layer 410 is formed in the drain opening 140. The first source layer 310 can extend outward from the source opening 130, and extend from one side of the gate electrode 200 to the other side of the gate electrode 200.

Still referring to FIG. 8, according to an embodiment of this disclosure, a second interlayer dielectric layer 152 can be formed on the first source layer 310 and the first drain layer 410. The second interlayer dielectric layer 152 can be formed through a deposition process, and the material and formation method of the second interlayer dielectric layer 152 can be the same as the material and formation method of the previously mentioned first dielectric layer 151. According to an embodiment of this disclosure, a patterning process can then be performed on the second interlayer dielectric layer 152 to form source opening 130 and drain opening 140 again, and expose the first source layer 310 and first drain layer 410 respectively.

Here's the translation:

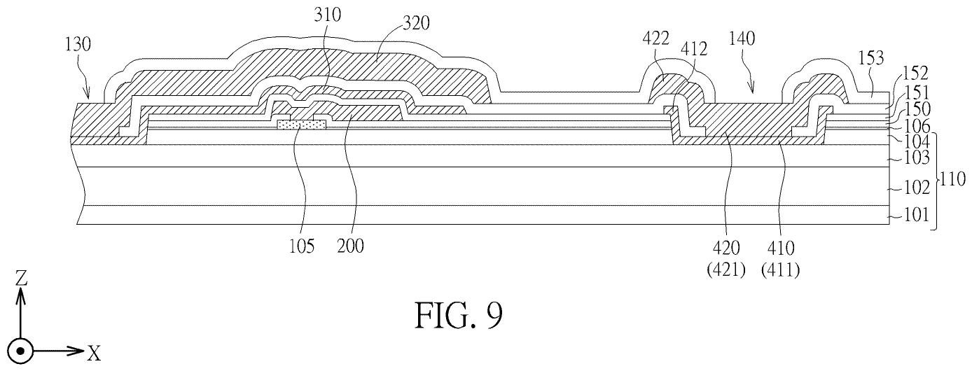

Referring to FIG. 9, according to an embodiment of this disclosure, a second conductive material layer (not shown) can be formed on the second interlayer dielectric layer 152, and then a patterning process is performed on the second conductive material layer to simultaneously form the mutually separated second source layer 320 and second drain layer 420. The second conductive material layer can be formed through a deposition process, and the material and formation method of the second conductive material layer can be the same as the material and formation method of the previously mentioned first conductive material layer. According to an embodiment of this disclosure, the second source layer 320 and the second drain layer 420 are electrically connected to the first source layer 310 and first drain layer 410 through the source opening 130 and drain opening 140, respectively.

Still referring to FIG. 9, according to an embodiment of this disclosure, a third interlayer dielectric layer 153 can be formed on the second source layer 320, second interlayer dielectric layer 152, and second drain layer 420. The third interlayer dielectric layer 153 can be formed through a deposition process, and the material and formation method of the third interlayer dielectric layer 153 can be the same as the material and formation method of the previously mentioned first interlayer dielectric layer 151. According to an embodiment of this disclosure, a patterning process can then be performed on the third interlayer dielectric layer 153 to form source opening 130 and drain opening 140 again, and expose the second source layer 320 and second drain layer 420 respectively.

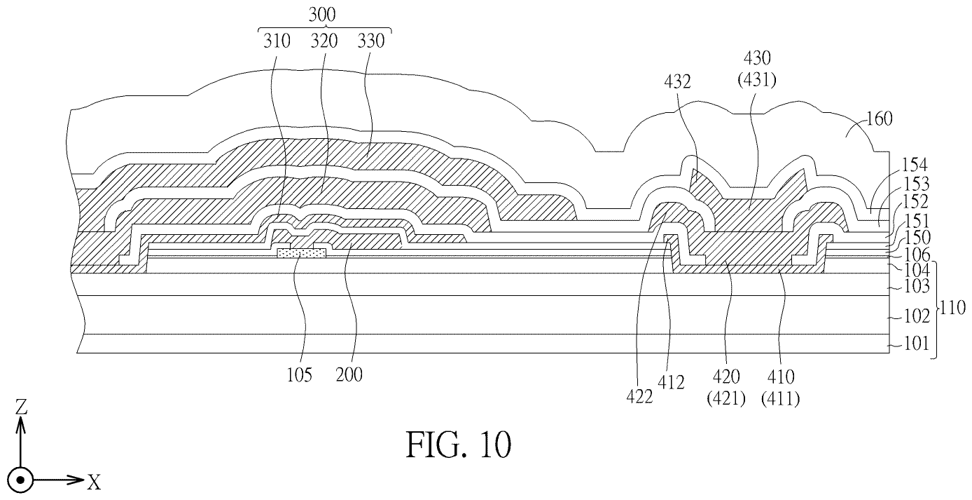

Referring to FIG. 10, according to an embodiment of this disclosure, a third conductive material layer (not shown) can be formed on the third interlayer dielectric layer 153, and then a patterning process is performed on the third conductive material layer to simultaneously form the mutually separated third source layer 330 and third drain layer 430. The third conductive material layer can be formed through a deposition process, and the material and formation method of the third conductive material layer can be the same as the material and formation method of the previously mentioned first conductive material layer. The third source layer 330 and third drain layer 430 are electrically connected to the second source layer 320 and second drain layer 410 through the source opening 130 and drain opening 140, respectively.

Still referring to FIG. 10, according to an embodiment of this disclosure, a fourth interlayer dielectric layer 154 can be formed on the third source layer 330 and third drain layer 430. The fourth interlayer dielectric layer 154 can be formed through a deposition process, and the material and formation method of the fourth interlayer dielectric layer 154 can be the same as the material and formation method of the previously mentioned first interlayer dielectric layer 151. According to an embodiment of this disclosure, the fourth interlayer dielectric layer 154 can be conformally formed on the third source layer 330 and third drain layer 430. Subsequently, an inter-metal dielectric layer 160 can be formed on the fourth interlayer dielectric layer 154, obtaining a structure similar to the embodiment shown in FIG. 1. Since the end edge of the third drain layer 430 and the end edge of the second drain layer 420 are staggered, when performing the deposition process to form the fourth interlayer dielectric layer 154 and inter-metal dielectric layer 160, the fourth interlayer dielectric layer 154 and inter-metal dielectric layer 160 can completely cover the region of the end edge of the third drain layer 430 without producing any voids in the fourth interlayer dielectric layer 154 and inter-metal dielectric layer 160, or even if voids exist, their maximum size can be less than 5 nanometers.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a semiconductor channel layer and a semiconductor barrier layer, disposed on the substrate;
a gate electrode disposed on the semiconductor barrier layer;
a first interlayer dielectric layer disposed on the semiconductor barrier layer and the gate electrode;
a source electrode disposed on one side of the gate electrode;
a drain stack layer disposed on the other side of the gate electrode and laterally separated from the gate electrode, the drain stack layer comprising:
a first drain layer comprising a first body portion and a first extension portion, wherein the first extension portion covers the first interlayer dielectric layer, and a bottom surface of the first extension portion is higher than a top surface of the first body portion;
a second drain layer disposed on the first drain layer and comprising a second body portion and a second extension portion, wherein the second extension portion covers the first extension portion, a length of the second drain layer is greater than a length of the first drain layer along a first direction, and a top surface of the second extension portion is higher than a top surface of the second body portion; and
a third drain layer disposed on the second drain layer and comprising a third body portion and a third extension portion.

2. The semiconductor device of claim 1, further comprising a drain opening in the first interlayer dielectric layer, wherein the first body portion is located within the drain opening.

3. The semiconductor device of claim 1, wherein the top surface of the second extension portion comprises a curved top surface.

4. The semiconductor device of claim 3, wherein the curved top surface is directly above the first extension portion.

5. The semiconductor device of claim 1, wherein the second extension portion extends beyond an end edge of the first extension portion.

6. The semiconductor device of claim 1, further comprising a second interlayer dielectric layer disposed between the first extension portion and the second extension portion, and covering the top surface of the first body portion.

7. The semiconductor device of claim 6, wherein a portion of the second interlayer dielectric layer is located within the drain opening.

8. The semiconductor device of claim 6, wherein the second interlayer dielectric layer comprises a raised region, and an apex of the raised region is higher than a bottom surface of the second extension portion.

9. The semiconductor device of claim 1, wherein a length of the third drain layer is smaller than the length of the first drain layer along the first direction, and the third extension portion is laterally separated from the first interlayer dielectric layer.

10. The semiconductor device of claim 1, wherein a length of the third drain layer is greater than the length of the second drain layer along the first direction, and the third extension portion covers and extends beyond the second extension portion.

11. The semiconductor device of claim 10, wherein the third extension portion comprises a curved top surface, and the curved top surface is disposed directly above the first extension portion.

12. The semiconductor device of claim 1, wherein a length of the second extension portion is 5%-30% of a distance between the drain structure and the gate electrode.

13. The semiconductor device of claim 1, further comprising an inter-metal dielectric layer disposed on the third drain layer, wherein the inter-metal dielectric layer comprises at least one void, and in a cross-sectional view, a maximum length of the at least one void is less than 5 nm.

14. A method of manufacturing a semiconductor device, comprising:
providing a substrate sequentially comprising a base, a semiconductor channel layer, and a semiconductor barrier layer from bottom to top;
forming a gate electrode on the bottom dielectric layer;
forming a first interlayer dielectric layer covering the gate electrode;
forming a source electrode on one side of the gate electrode;
forming a first drain layer on the other side of the gate electrode, wherein the first drain layer comprises a first body portion and a first extension portion, and the first extension portion covers a portion of the first interlayer dielectric layer; and
forming a second drain layer on the first drain layer, wherein the second drain layer comprises a second body portion and a second extension portion, and the second extension portion covers a second interlayer dielectric layer, wherein a length of the second drain layer is greater than a length of the first drain layer in a first direction, and a top surface of the second extension portion is higher than a top surface of the second body portion.

15. The method of manufacturing the semiconductor device according to claim 14, wherein after forming the second drain layer, further comprising:
forming a third interlayer dielectric layer covering the second extension portion and the second interlayer dielectric layer; and
forming a third drain layer on the second drain layer, wherein the third drain layer comprises a third body portion and a third extension portion.

16. The method of manufacturing the semiconductor device according to claim 14, wherein before forming the gate electrode, further comprising:
forming a bottom dielectric layer on the semiconductor barrier layer, wherein the bottom dielectric layer comprises a gate opening, and the gate electrode is located within the gate opening.

17. The method of manufacturing the semiconductor device according to claim 14, wherein a length of the third drain layer is less than or equal to a length of the second drain layer along the first direction, and the third extension portion covers a portion of the second extension portion.

18. The method of manufacturing the semiconductor device according to claim 14, wherein a length of the third drain layer is greater than a length of the second drain layer along the first direction, and the third extension portion covers and extends beyond an end edge of the second extension portion.
